(19) United States
(12) Patent Application Publication
(10) Pub. No.: US 2026/0228405 A1
(43) Pub. Date: Aug. 6, 2026

(54) METHOD, ELECTRONIC DEVICE, AND NON-TRANSITORY COMPUTER READABLE MEDIUM FOR DESIGN RULE CHECK

(71) Applicant: Taiwan Semiconductor Manufacturing Company, Ltd., Hsinchu (TW)

(72) Inventors: Hsin Ying Lin, Hsinchu (TW); Shu-Cheng Li, Hsinchu City (TW); Huang-Yu Chen, Hsinchu County (TW); Chih-Wei CHANG, New Taiepi City (TW); Yun-Han Lee, Hsinchu County (TW)

(73) Assignee: Taiwan Semiconductor Manufacturing Company, Ltd., Hsinchu (TW)

(21) Appl. No.: 19/044,644

(22) Filed: Feb. 4, 2025

(51) Int. Cl. G06F 30/392; G06F 30/398

(52) U.S. Cl. CPC G06F 30/392; G06F 30/398

(57) ABSTRACT

Design method, electronic device, and non-transitory computer readable medium. The design method is for checking layout of a semiconductor device. The design method comprising: obtaining a layout file; checking the layout file according to an angle rule to identify an angle rule violating region in the layout file; checking the layout file according to a distance rule to identify a distance rule violating region corresponding to the angle rule violating region in the layout file; and modifying the layout file according to the distance rule violating region to fix both of the angle rule violating region and the distance rule violating region.

### BACKGROUND

As semiconductor technology evolves, it becomes possible to design a semiconductor package imposing routings with arbitrary angles.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a cross-section of a semiconductor package 1 in accordance with some embodiments.

FIG. 2A illustrates a layout diagram in accordance with some embodiments.

FIG. 2B illustrates a layout diagram in accordance with some embodiments.

FIG. 2C illustrates a layout diagram in accordance with some embodiments.

FIG. 3 illustrates a flowchart of a design method in accordance with some embodiments.

FIGS. 4A-4D illustrate a process of how the design method in FIG. 3 is performed in accordance with some embodiments.

FIGS. 5A-5D illustrate a process of how the design method in FIG. 3 is performed in accordance with some embodiments.

FIGS. 6A-6C illustrate a process of modifying the layout in accordance with some embodiments.

FIGS. 7A-7C illustrate a process of modifying the layout in accordance with some embodiments.

FIGS. 8A-8D illustrate a layout modifying process in accordance with some embodiments.

FIG. 9 illustrates a flowchart of a design method in accordance with some embodiments.

FIG. 10 illustrates a block diagram of an electronic device 100 in accordance with some embodiments.

### DESCRIPTION OF THE EMBODIMENTS

As the technology evolves, 3D-IC has attracted extensive attention due to its compatibility to high performance computing (HPC). Different package methods have been developed to realize the 3D-IC fabrication, such as chip-on-wafer-on-substrate (CoWoS) chip package, integrated fan-out (InFO) chip package, etc.

IC packaging has evolved such that multiple ICs can be vertically stacked in the 3D packages in order to save horizontal area on a printed circuit board (“PCB”). An alternative packaging technique, referred to as a “2.5D package,” can use an interposer structure, which may be formed from a semiconductor material, such as silicon, for coupling one or more semiconductor dies to a PCB. ICs or other semiconductor dies, which may incorporate heterogeneous technologies, can be mounted on the interposer. In addition to being joined to the IC dies, the interposer can also be joined to the PCB and to a package substrate disposed between the PCB and the interposer.

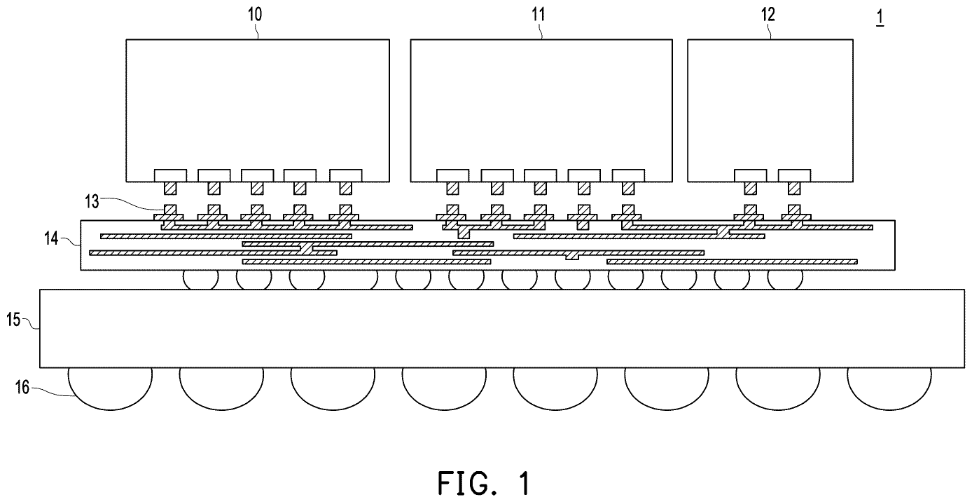

FIG. 1 illustrates a cross-section of a semiconductor package 1 in accordance with some embodiments. The semiconductor package 1 is fabricated using the CoWoS chip package. The semiconductor package 1 is configured to put the multiple semiconductor dies 10-12 together in a single package. Particularly, the semiconductor dies 10-12 are disposed on an interposer 14 and electrically coupled through μbumps 13. The interposer 14 is formed by multiple redistribution layers. Each redistribution layer is patterned by conductive routings so as to provide electrical connections for the semiconductor dies 10-12 on the top surface. In some embodiments, the semiconductor dies 10, 11 may be logic dies and the semiconductor die 12 may be a memory die. The semiconductor dies 10, 11 may be coupled to access the memory die 12 for performing desired computations. The computation results of the semiconductor dies 10, 11, 12 are further outputted to the back side of the interposer 14, and further to the substrate 15 and arrive at a ball grid array 16 for external access. In brief, the semiconductor package 1 is configured to integrate the multiple semiconductor dies 10-12 in the single package leveraging the vertical-stacking technology, thereby improving calculation speed and manufacturing cost.

Generally speaking, layouts in the semiconductor dies 10-12 are arranged in orthogonal directions, meaning that almost all elements in the semiconductor dies 10-12, such as conductive routings, diffusion, channels, etc., are arranged along an X-direction and a Y-direction which are perpendicular to each other. In such circumstances, an intersection angle of any two components may be substantially 90°. In some embodiments, other than the X-direction and Y-direction, the components in the semiconductor package 1 may be designed and arranged along an oblique angle, or even with a round edge, providing more flexibilities to layouts with different needs.

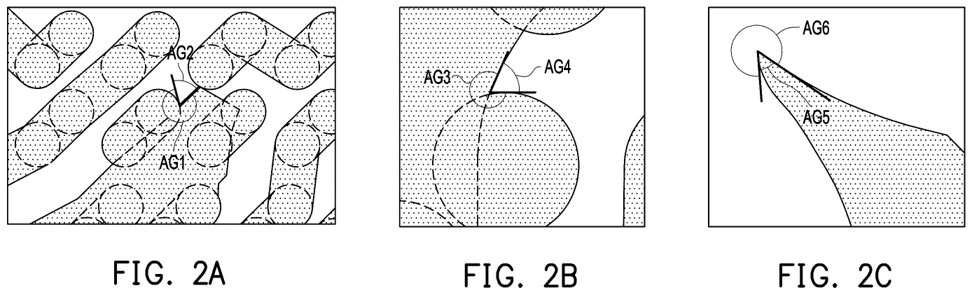

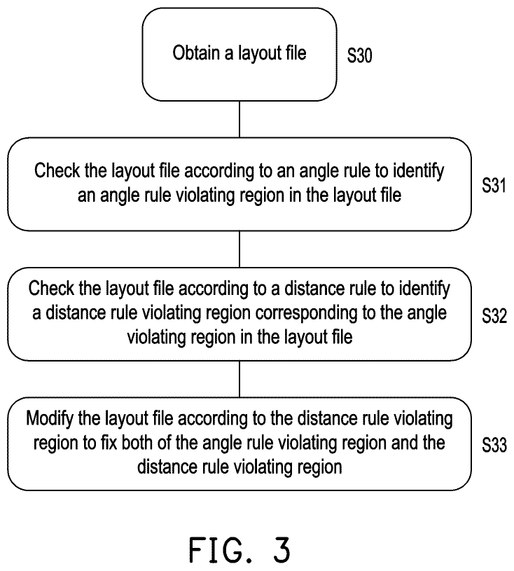

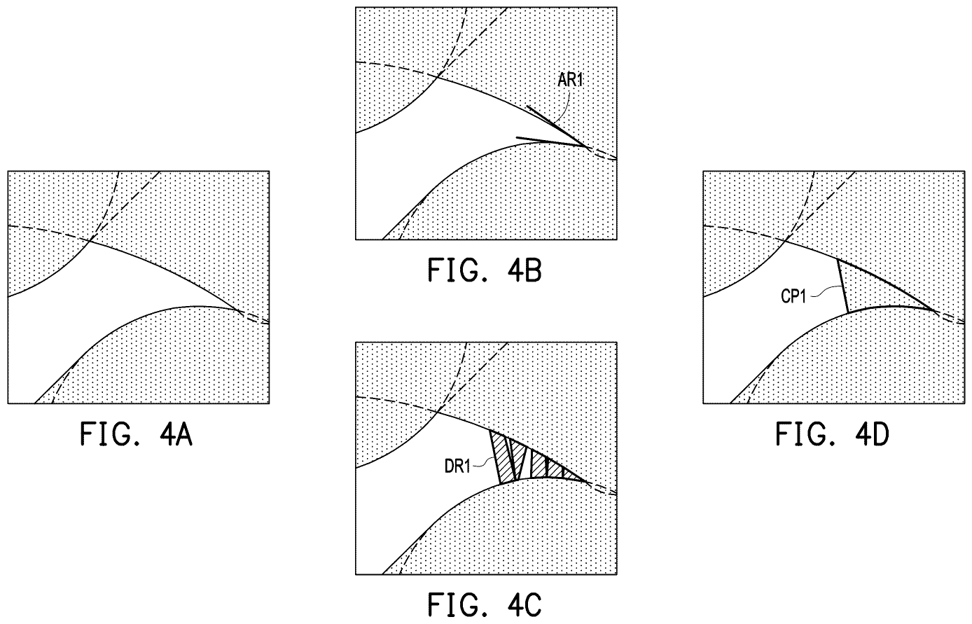

FIG. 2A illustrates a layout diagram in accordance with some embodiments. In some embodiments, the layout diagram is stored as a graphical data system (GDS) file for access. In some embodiments, the layout diagram in FIG. 2A may be a redistribution layer in the interposer 14 in FIG. 1. In some embodiments, the layout diagram in FIG. 2A may be for other semiconductor components in the semiconductor package 1 in FIG. 1.

As can be seen in the layout diagram in FIG. 2A, the redistribution layer includes conductive routings arranged in arbitrary shapes angles and shapes. Particularly, the conductive routings may be arranged in oblique angles with rounded edges. Owing from the oblique angle, the intersection angle for any two elements may be varied, so that an acute angle or an obtuse angle may also occur. For example, as marked in FIG. 2A, angles AG1, AG2 defined by edges of the conductive routing are formed. The angle AG1 may refer to an angle internal to the conductive routing, and the angle AG2 may refer to an angle external to the conductive routing. In this example, the angle AG1 is greater than 270°, and the angle AG2 is less than 90°, and the angles AG1, AG2 are explementary angles and together have a sum of 360°. Usually, the dielectric materials are often used to cover the conductive routings in the interposer. The surrounded dielectric material may be used to fill in the space of the angle AG2, thereby forming a tip shaped structure which is more likely to crack.

FIG. 2B illustrates a layout diagram in accordance with some embodiments. In some embodiments, the layout diagram in FIG. 2B may be a redistribution layer in the interposer 14 in FIG. 1. In this embodiment, explementary angles AG3, AG4 are formed. Similar to the angles AG1, AG 2, the angle AG3 internal to the conductive routing may be greater than 270°, and the angle AG4 external to the conductive routing may be less than 90°. The dielectric material may be used to fill in the space of the angle AG4.

FIG. 2C illustrates a layout diagram in accordance with some embodiments. In some embodiments, the layout diagram in FIG. 2B may be a redistribution layer in the interposer 14 in FIG. 1. In this embodiment, explementary angles AG5, AG6 are formed. The angle AG5 internal to the conductive routing may be less than 90°, and the angle AG6 external to the conductive routing may be greater than 270°. In this embodiment, it is the conductive routing that forms the tip shaped structure.

As illustrated and described in relation to FIGS. 2A-2C, providing the options of oblique angles and arch edges in the layout design may be beneficial to flexible design process, but also brings out different design challenges. For example, the intersection angle that is too small may lead to a weaker structural strength and more vulnerable to crack or other reliability issues. Moreover, although the interposer 14 in the semiconductor package 1 is taken as the examples in FIGS. 2A-2C, the layouts may also be applied other structures, such as the semiconductor dies 10-12 or the substrate 15 in the semiconductor package 1.

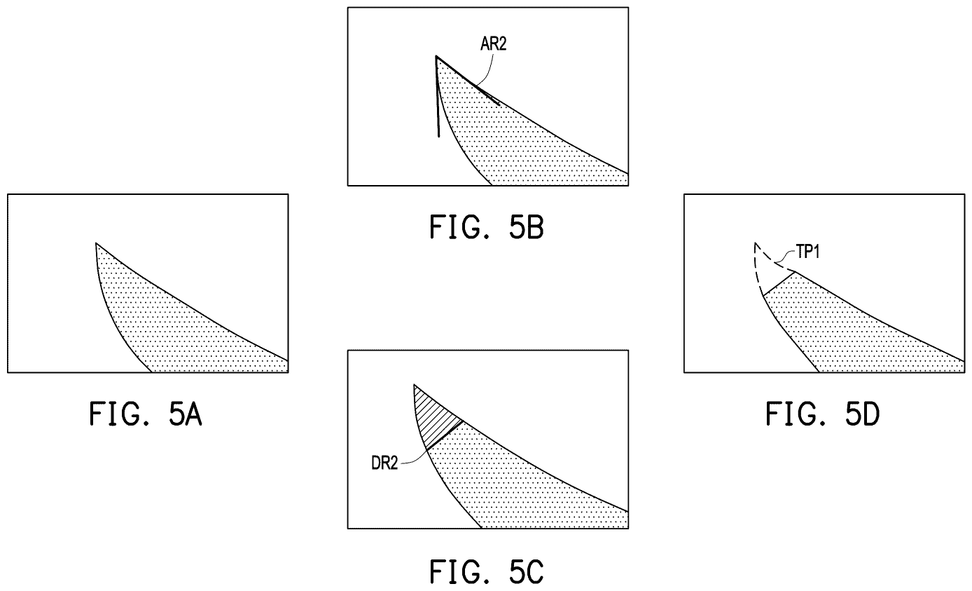

FIG. 3 illustrates a flowchart of a design method in accordance with some embodiments. The design method may be utilized to modify a layout. The layout may be a layout diagram in one of the semiconductor dies 10-12, the interposer 14, and the substrate 15 in the semiconductor package 1 in FIG. 1. The design method may be utilized to assist a design procedure of the layout during the design process, which will be described in greater details in paragraphs below. Particularly, the design method may be used to help fixing certain reliability issues which may be aroused by oblique and/or round edges in the layout.

The design method includes steps S30-S33. In step S30, a layout file is obtained. The layout file may be, for example but not limited to a GDS file (also referred as a GDSII file), a Gerber filer, or the like. The layout file may record a floorplan of all elements arranged in the semiconductor device. Taking the GDS file as the layout file as an example, the GDS file records all vertices of the patterned elements in the layout diagram.

In step S31, an angle rule is used to check or examinate the layout file to identify an angle rule violating region in the layout file. Specifically, the layout file may record an oblique line using two vertices on both ends of the oblique line. As for circles or rounded edges in the layout, the layout file may approximate the circular shape using a polygonal shape. For example, a circular shape in the layout may be approximated by a triacontadigon, a hexacontatetragon, or other suitable polygon shapes. By using polygon shapes, a circular shape may be represented by a plurality of vertices and edges of the approximated polygon shape.

Since all edges, whether straight or rounded edges, in the layout file are recorded by vertices, the design method may examine an angle formed by any three connected vertices to see whether there is any angle rule violation. If there is any angle formed by three connected vertices outside the predetermined angle range, an angle rule violating region including the three connected vertices will be marked for further correction.

Specifically, the angle rule may require that all intersection angles in the layout file within the predetermined angle range. In some embodiments, the predetermined angle range may be between 90° to 270°. By limiting the angle within the predetermined angle range, all intersection angles within the layout file may be set as a right angle of 90° or an obtuse angle within the predetermined angle range.

In step S32, a distance rule is used to check the layout file to identify a distance rule violating region in the layout file. The distance rule may include a spacing rule and/or a width rule. For the spacing rule, it requires that a gap width between two close edges of a gap be greater than or equal to a minimum spacing value. As for the width rule, it requires that a patterned element width between two close edges of an element be greater than or equal to a minimum width value. In some embodiments, the minimum width value is a width selected from 1 μm to 100 μm.

Generally speaking, when there is the angle rule violation in the layout and the angle rule violating region is identified, it is highly likely that a distance rule violation is occurring in the same or neighboring region. It is because that when the intersection angle is either too large (e.g., greater than 270°) or too small (e.g., less than 90°), it creates the narrow gap or the narrow-patterned element width, prone to reliability issues.

In step S33, the layout is modified using the distance rule violating region in order to fix both of the angle rule violating region and the distance rule violating region. Specifically, since the distance rule violation comes up with the angle rule violation, fixing the distance rule violation may cover most angle rule violations.

In some embodiments, when there is a spacing rule violation, a concave patch may be added to the angle identified in the angle rule violating region. In order to resolve the angle rule and the spacing rule at the same time, an edge of the concave patch may be properly determined to meet both the angle rule and the spacing rule. In other words, the determined edge of the concave patch has a length greater than the minimum spacing width, and two intersection angles at both ends of the edge of the concave patch are both within the predetermined angle range.

In some embodiments, when there is a width rule violation, a tip portion may be removed from the layout to the angle identified in the angle rule violating region. In order to resolve the angle rule and the width rule at the same time, an edge of the tip portion may be properly determined to meet both the angle rule and the spacing rule. In other words, the determined edge of the tip portion has a length greater than the minimum width value, and two intersection angles at both ends of the edge of the tip portion are both within the predetermined angle range.

Details regarding how the edge of the concave patch and the edge of the tip portion are determined will be described in greater details in paragraphs below.

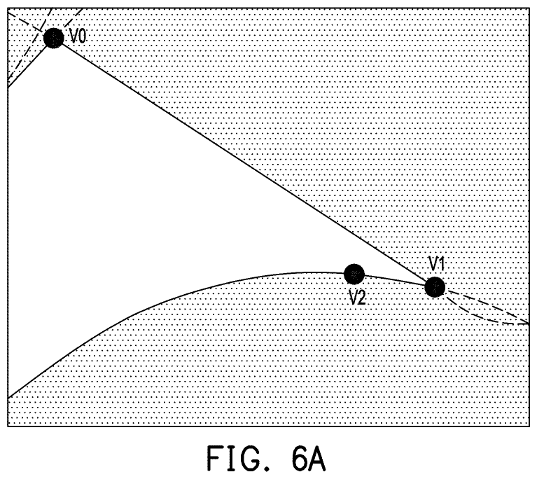

FIGS. 4A-4D illustrate a process of how the design method in FIG. 3 is performed in accordance with some embodiments. Specifically, FIGS. 4A-4D respectively corresponds to operations performed in steps S30-S33 in FIG. 3. In this embodiment, the layout diagrams in FIGS. 4A-4D are used to explain operations resolving an angle rule violation and a corresponding spacing rule violation.

In step S30, when a layout file is provided, a part of the layout file may include the layout diagram as illustrated in FIG. 4A, which includes oblique and rounded edges.

In step S31, after checking the layout file using the angle rule, an angle rule violating region AR1 falling outside the predetermined angle range may be identified in FIG. 4B. In this embodiment, the angle rule violating region AR1 may be identified by two straight lines using tangent slopes of the curvy edges at the intersection angle. In this embodiment, the angle formed by the edges are too large, causing a narrow gap formed between the edges of the patterned element.

In step S32, after checking the layout file using the distance rule, a distance rule violating region DR1 having a gap width less than the minimum spacing value may be identified in FIG. 4C. In this embodiment, the distance rule violating region DR1 may be identified and marked by a straight line, which may be used as the edge of the concave patch in the following step.

In step S33, a concave patch CP1 may added in the layout in FIG. 4D to fill in the gap formed by the acute angle, so as to resolve the angle rule violating region AR1 and the distance rule violating region DR1 at the same time.

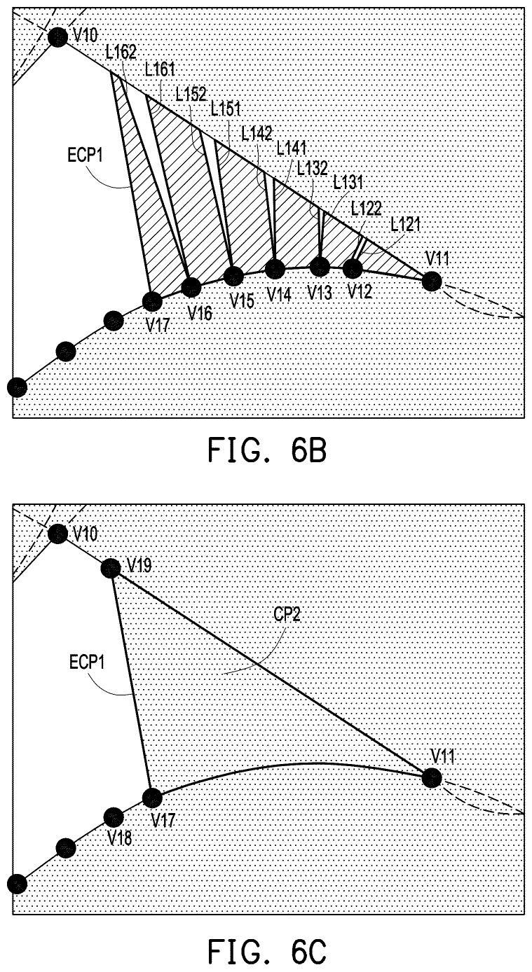

FIGS. 5A-5D illustrate a process of how the design method in FIG. 3 is performed in accordance with some embodiments. Specifically, FIGS. 5A-5D respectively corresponds to operations performed in steps S30-S33 in FIG. 3. In this embodiment, the layout diagrams in FIGS. 5A-5D are used to explain operations resolving an angle rule violation and a corresponding width rule violation.

In step S30, when a layout file is provided, a part of the layout file may include the layout diagram as illustrated in FIG. 5A, which includes oblique and rounded edges.

In step S31, after checking the layout file using the angle rule, an angle rule violating region AR2 falling outside the predetermined angle range may be identified in FIG. 5B. In this embodiment, the angle rule violating region AR2 may be identified by two straight lines using tangent slopes of the curvy edges at the intersection angle. In this embodiment, the angle formed by the edges are too small, causing a narrow tip portion formed at the intersection. In some embodiments, the small intersection angle may also be referred as a convex shape.

In step S32, after checking the layout file using the distance rule, a distance rule violating region DR2 having a patterned element width less than the minimum width value may be identified in FIG. 5C. In this embodiment, the distance rule violating region DR2 may be identified and marked by a straight line, which may be used as an edge of a tip portion in the following step.

In step S33, the tip portion TP1 may be removed from the layout, so as to resolve the angle rule violating region AR2 and the distance rule violating region DR2 at the same time.

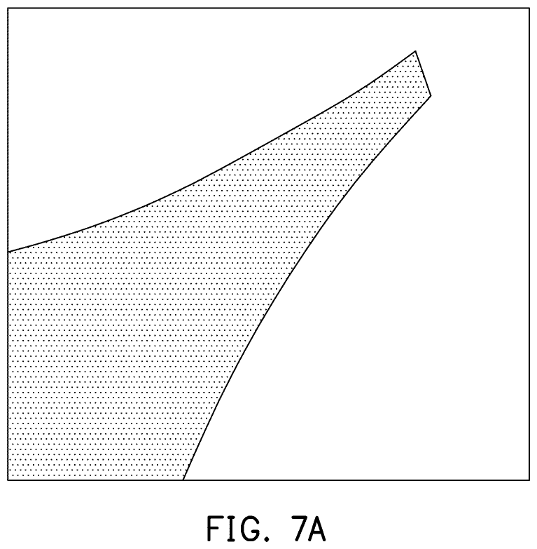

FIGS. 6A-6C illustrate a process of modifying the layout in accordance with some embodiments.

In step S30, a layout file as depicted in FIG. 6A is obtained. As can be seen in FIG. 6A, the layout file contains a substantially acute angle and a narrow spacing.

In step S31, the layout is checked using the angle rule to identify the angle rule violating region. As can be seen in FIG. 6B, vertices V10-V17 in the layout file are labeled. The angle rule requires that an angle formed by any three connected vertices in the layout to be within the predetermined angle range. In this embodiment as illustrated in FIG. 6A, the angle formed by the vertices V0-V2 is too large and outside the predetermined angle range, making this angle as an angle rule violating region. However, for the sake of simplicity, the marker of the angle rule violating region is omitted in FIG. 6B.

In step S32, the layout is checked using the spacing rule to identify the spacing rule violating region. The distance rule includes the spacing rule and the width rule. In this embodiment, the layout file is violating the spacing rule, which requires that a gap width to be greater than a minimum spacing value.

To check whether the layout file meets the spacing rule, at least one gap value of each vertex will be calculated. Specifically, for each vertex, at least one vertical line extending outward from the vertex may be drawn to determine the gap value. In this embodiment, since one of the sides forming the angle rule violating region is an arch or a rounded edge and approximated by the vertices V10-V17, two vertical lines are drawn from the corresponding vertex based on slopes of the connection line to the adjacent vertices on both sides. For example, for the vertex V12, vertex lines L121 and L122 respectively perpendicular to the line connected by the vertices V11-V12 and the line connected by the vertices V12-V13 are drawn. Similarly, vertical lines L131, L132 are drawn from the vertex V13, vertical lines L141, L142 are drawn from the vertex V14, and so on.

The vertical lines may be used to determine a gap value of the corresponding vertex. Specifically, for each vertical line, a segment length from the corresponding vertex to the intersection edge may be determined. For those vertices with only one vertical line drawn from each, the segment length may be determined as the gap value of the corresponding vertex. However, for those vertices on the rounded edges and two vertical lines are drawn from each, two segment lengths are determined, and the shorter gap value may be chosen as the gap value of the corresponding vertex.

After the gap value of each vertex is determined, the gap value may be compared with the minimum spacing value to see whether there is any spacing rule violation. If the comparison result shows that the gap value is less than the minimum spacing value, the corresponding vertex may be identified. Otherwise, the corresponding vertex may be recognized as passed the spacing rule.

After the spacing rule is applied to and checked on all vertices in the layout file, a selected vertex may be determined to fill in a concave patch fixing both of the angle rule and the spacing rule. Specifically, the distance violation usually comes along with the angle rule violation. To properly correlate the dependent violating regions, each vertex connected to the three vertices identified as violating the angle rule will be sequentially searched and examined according to the spacing rule until the first vertex meeting the spacing rule is found.

Taking FIG. 6B as an example, the vertex V12 is the first vertex coupled on one edge to the three vertices V10-V12, so a condition of whether the vertex V12 meeting the spacing rule will be examined first. After finding out that the vertex V12 violates the spacing rule, the search will go to the vertex V13 for the same process of examining its condition of whether the spacing rule is met. In this embodiment, the vertices V12-V16 are identified as violating the spacing rule, so the search will stop at the vertex V17 and determining the vertex V17 as the selected vertex.

After the selected vertex V17 is chosen, the selected vertex V17 may be utilized to draw an edge ECP1 of a concave patch. To meet both of the angle rule and the spacing rule, the edge ECP1 is a line segment starting from the selected vertex V17, intersecting another edge of the three vertices V10-V12 violating the angle rule, and also having a segment length of the minimum spacing value. In this way, the length of the edge ECP1 is equal to the minimum spacing value, and two intersection angles at both ends of the edge ECP1 are both within the predetermined angle range, so that both the angle rule and the spacing rule are met.

In step S63 and as depicted in FIG. 6C, a concave patch CP2 may be added in the layout using the edge ECP1 as a boundary. In the modified layout, both of the intersection angles formed by the vertices V10, V19, V17 and the vertices V19, V17, V18 are within the predetermined angle range, while the spacing also meets the spacing rule. Therefore, both of the angle rule and the spacing rule are resolved based on the edge ECP1 determined using the spacing rule.

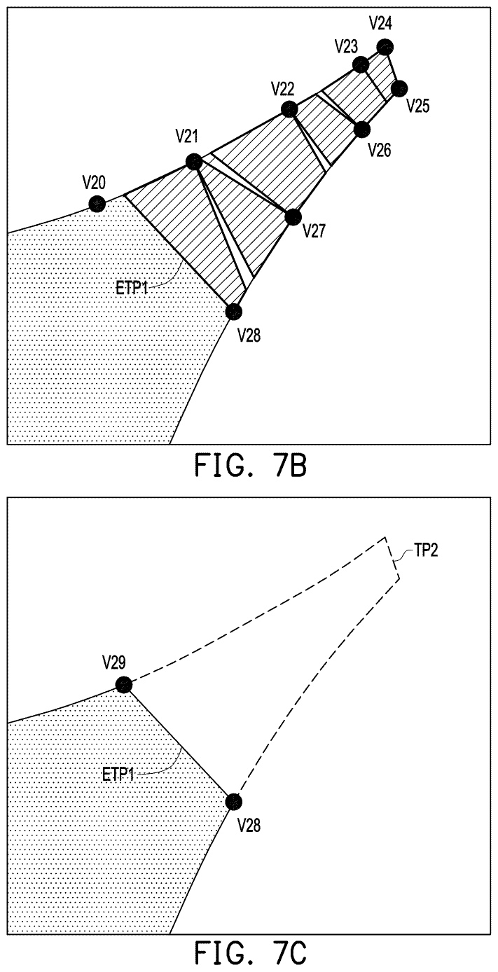

FIGS. 7A-7C illustrate a process of modifying the layout in accordance with some embodiments.

In step S30, a layout file as depicted in FIG. 7A is obtained. As can be seen in FIG. 7A, the layout file contains a substantially acute angle and narrow patterned element width.

In step S31, the layout is checked using the angle rule to identify the angle rule violating region. As can be seen in FIG. 7B, vertices V20-V28 in the layout file are labeled. The angle rule requires that an angle formed by any three connected vertices in the layout to be within the predetermined angle range. In this embodiment as illustrated in FIG. 7A, the angle formed by the vertices V23, V24, V25 is too small and outside the predetermined angle range, making this angle as an angle rule violating region. However, for the sake of simplicity, the marker of the angle rule violating region is omitted in FIG. 7B.

In step S32, the layout is checked using the distance rule to identify the distance rule violating region. The distance rule includes the spacing rule and the width rule. In this embodiment, the layout file is violating the width rule, which requires that a patterned element width to be greater than or equal to a minimum width value.

To check whether the layout file meets the width rule, at least one width value of each vertex will be calculated. Similar to the process of determining the gap value, at least one vertical line is drawn from each vertex to determine the width value. For those vertices with only one vertical line drawn from each, the segment length may be directly determined as the width value of the corresponding vertex. However, for those vertices on the rounded edges and two vertical lines are drawn from each, two segment lengths are determined, and the shorter width value may be chosen as the width value of the corresponding vertex.

After the width value of each vertex is determined, the width value may be compared with the minimum width value to see whether there is any width rule violation. If the comparison result shows that the width value is less than the minimum width value, the corresponding vertex may be identified. Otherwise, the corresponding vertex may be recognized as passing the width rule.

After the width rule is applied to and checked on all vertices in the layout file, a selected vertex may be determined to remove a tip portion fixing both of the angle rule and the width rule. Specifically, the width rule violation usually comes along with the angle rule violation. To properly correlate the dependent violating regions, each vertex connected to the three vertices identified as violating the angle rule will be sequentially searched and examined according to the width rule until the first vertex meeting the distance rule is found.

Taking FIG. 7B as an example, the vertex V26 is the first vertex coupled on one edge to the three vertices V23, V24, V25, so the width rule will be used on the examination to the vertex V26 first. After finding out that the vertex V26 violates the width rule, the search will go to the vertex V21, and so on, until the vertex V28 meeting the width rule is found.

After the selected vertex V28 is chosen, the selected vertex V28 may be utilized to draw an edge ETP1 of a tip portion. To meet both of the angle rule and the width rule, the edge ETP1 is a line segment starting from the selected vertex V28, intersecting another edge of the extending from the three vertices V23-V24 violating the angle rule, and also having a segment length of the minimum width value. In this way, the length of the edge ETP1 is equal to the minimum width value, and two intersection angles at both ends of the edge ETP1 are both within the predetermined angle range, so that both the angle rule and the width rule are met.

In step S63 and as depicted in FIG. 7C, a tip portion TP1 may be removed from the layout using the edge ETP1 as a boundary. In the modified layout, both of the intersection angles formed at both ends of the vertices V28, V29 are within the predetermined angle range, while the width value also meets the width rule. Therefore, both of the angle rule and the width rule are resolved based on the edge ETP1 determined using the width rule.

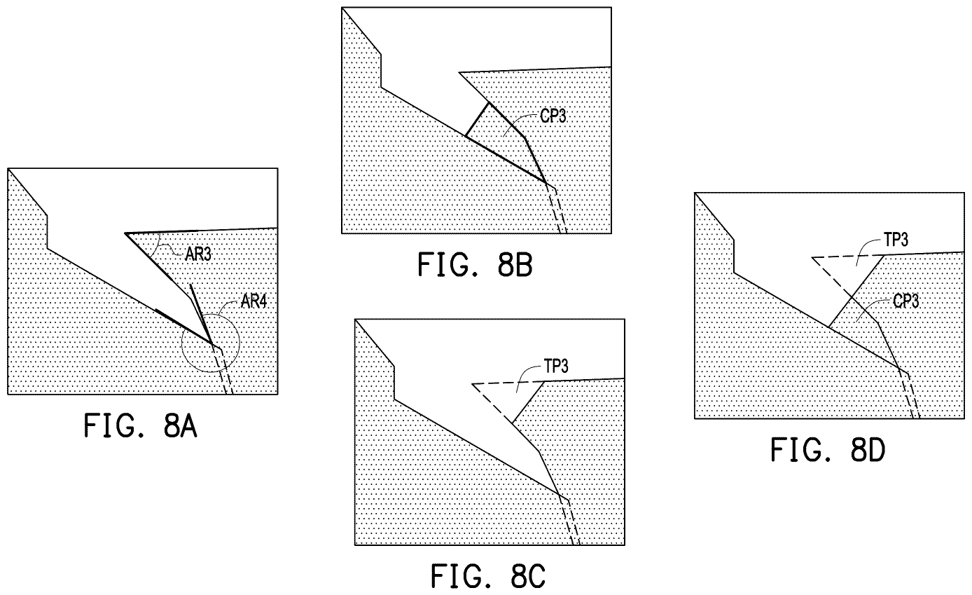

FIGS. 8A-8D illustrate a layout modifying process in accordance with some embodiments.

In FIG. 8A, a layout file includes multiple angle rule violating regions AR3, AR4. The angle rule violating region AR3 identifies an angle that is too small, while the angle rule violating region AR4 identifies an angle that is too large. To fix the angle violating regions AR3, AR4, a tip portion may be removed from the angle rule violating region AR3 and a concave patch may be filled in the angle rule violating region AR4. However, the order to remove the tip portion and to add the concave patch is not limited.

FIGS. 8A, 8B, 8D illustrate the layout modifying process that adding the concave portion is executed before removing the tip portion. As can be seen in FIG. 8B, a concave patch CP3 is added to the angle violating region AR4, and in FIG. 8D, a tip portion TP3 is removed thereafter.

FIGS. 8A, 8C, 8D illustrate the layout modifying process that adding the concave portion is executed after removing the tip portion. As can be seen in FIG. 8C, the tip portion TP3 is removed, and in FIG. 8D, the concave patch CP3 is added to the angle violating region AR4 thereafter.

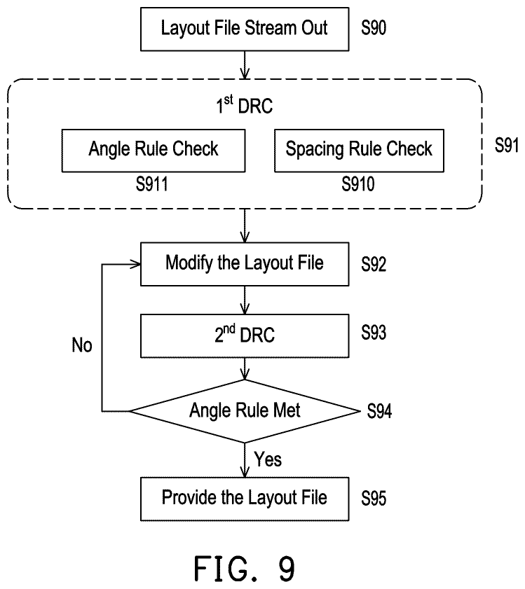

FIG. 9 illustrate a flowchart of a design method in accordance with some embodiments. The design method may be applied to check a layout file and perform necessary modifications on it if necessary.

Specifically, the design method includes steps S90-S95. In step S90, a layout file is streamed out. The layout file may be, for example but not limited to a GDS file (also referred as a GDSII file), a Gerber filer, or the like. The layout file may record a floorplan of all elements arranged in the semiconductor device. Taking the GDS file as the layout file as an example, the GDS file records all vertices of the patterned elements in the layout diagram.

In step S91, a design rule check (DRC) is applied on the layout file. Specifically, the DRC is to check whether patterns of all elements in the layout file meet required sizes, spacings, widths, etc. In this embodiment, the design rule may include an angle rule and a distance rule, and the angle rule check and the distance rule check are respectively included in step S911 and S910 of step S91. Please refer to steps S31, S32 described in relation to FIG. 3 for more details about the angle rule check and the distance rule check, which are omitted herein. Further, the order of performing the angle rule check and the distance rule check is not limited. The angle rule check may be performed prior to, subsequent to, simultaneously with the distance rule check. Further, the DRC may generate a DRC result indicating the angle rule violating region and the corresponding distance rule violating region if there is any.

In step S92, the layout file may be modified based on the DRC result generated. Specifically, the angle rule violating region in the layout file may be modified based on the distance rule check result (i.e., the distance rule violating region). When the angle rule check result shows that an angle is too small and out of the predetermined angle range, a tip portion at the angle rule violating region may be determined based on the distance rule check result and removed. On the other hand, when the angle rule check result shows that an angle is too large and out of the predetermined angle range, a concave patch at the angle rule violating region may be determined based on the distance rule check result and filled in. Please refer to steps S33 described in relation to FIG. 3 for more details about the modifications on the layout file, which are omitted herein.

After modifications on the layout file is completed, in step S93 another the DRC may be performed on the modified layout file. The second DRC in step S93 is similar to the first DRC in step S91 which includes the angle rule check and the distance rule check.

In step S94, the second DRC result will be evaluated to decide whether another modification should be applied. In some embodiments, to ensure that modifications on the layout does not cause any further angle rule violating regions, the second DRC may be performed on the modified layout file. If the second DRC result shows that the angle rule is not met in the modified layout file, the design method may proceed to step S92 for another layout modification. Otherwise, if the second DRC result shows that the angle rule is met in the modified layout file, the design method may proceed to step S95 for providing the modified layout file.

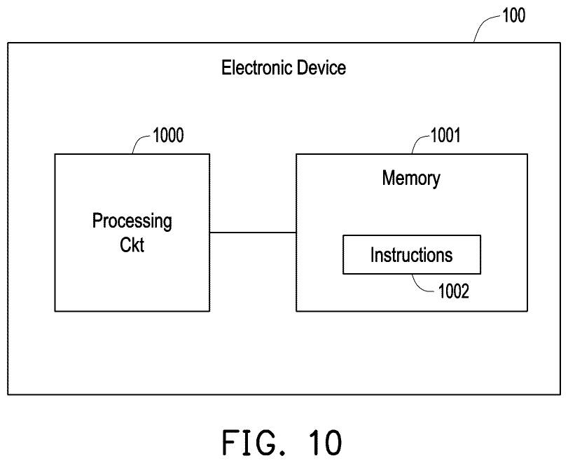

FIG. 10 illustrates a block diagram of an electronic device 100 in accordance with some embodiments. The electronic device 100 includes a processing circuit 1000 and a memory 1001. The memory 1001 may be configured to store instructions, so that the processing circuit 1000 may be configured to access the memory 1001 for performing the design method as illustrated in FIG. 3 or FIG. 9. Details of the design method are recited in paragraphs above in relation to FIGS. 3, 9, which are omitted herein.

In some embodiments, the electronic device 100 may be utilized for circuit design. Moreover, one or more electronic design automation (EDA) tools may be installed in this electronic device 100 and utilized to design, optimize, and verify semiconductor device designs, such as circuit designs in a semiconductor chip. After the layout file is generated by placement route algorithm or by a full-custom design manner, the resulting electronic device 100 may be used to check for compliance with various design rules, design specifications, or the like. For example, the electronic device 100 may be used to check for various design rule check (DRC) violations. Further, the electronic device 100 may be used to modify the layout file is there is angle rule violations in the layout file.

Examples of the processing circuit 1000 include, but not limited to, a central processing unit (CPU), a microprocessor, an application specific integrated circuit, a graphics processing unit, a field programmable gate array, an advanced RISC machine or combinations thereof. In addition, the processing circuit 1000 may also be implemented through synthesis using hardware description language (HDL), such as high-speed hardware description language (VHDL), verilog or the like.

Examples of the memory 1001 may include one or more non-transitory computer-readable mediums, including by way of non-limiting example, a hard drive, solid-state drive, external storage, redundant array of independent disks (RAID), network-attached storage, optical storage, tape drive, backup system, cloud storage, or any combination of the foregoing. The memory 1001 may be, or may include therein, a database or databases or data stored in other configurations, and may include a stored copy of operational software such as operating system and/or software portions of the electronic device 100. Many other configurations are also possible, and are intended to be encompassed within the broad scope of this specification.

In some embodiments, a design method is to check layout of a semiconductor device. The design method comprises: obtaining a layout file; checking the layout file according to an angle rule to identify an angle rule violating region in the layout file; checking the layout file according to a distance rule to identify a distance rule violating region corresponding to the angle rule violating region in the layout file; and modifying the layout file according to the distance rule violating region to fix both of the angle rule violating region and the distance rule violating region.

In some embodiments, an electronic device is configured to check layout of a semiconductor device. The electronic device comprises a memory and a processing circuit. The memory configured to store an instruction code. The processing circuit coupled to the memory to access the instruction code, the processing circuit being configured to perform the following steps according to the instruction code: obtain a layout file; check the layout file according to an angle rule to identify an angle rule violating region in the layout file; check the layout file according to a distance rule to identify a distance rule violating region corresponding to the angle rule violating region in the layout file; and modify the layout file according to the distance rule violating region to fix both of the angle rule violating region and the distance rule violating region.

In some embodiments, a non-transitory computer readable medium is configured to instructions for execution by a processing circuit for: obtaining a layout file; checking the layout file according to an angle rule to identify an angle rule violating region in the layout file; checking the layout file according to a distance rule to identify a distance rule violating region corresponding to the angle rule violating region in the layout file; and modifying the layout file according to the distance rule violating region to fix both of the angle rule violating region and the distance rule violating region.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A design method to check layout of a semiconductor device, the design method comprising:
obtaining a layout file;
checking the layout file according to an angle rule to identify an angle rule violating region in the layout file;
checking the layout file according to a distance rule to identify a distance rule violating region corresponding to the angle rule violating region in the layout file; and
modifying the layout file according to the distance rule violating region to fix both of the angle rule violating region and the distance rule violating region.

2. The design method of claim 1, wherein the layout file is a graphical data system (GDS) file recording a plurality of vertices.

3. The design method of claim 1, wherein the angle rule comprises that an angle formed by three connected vertices is within a predetermined angle range.

4. The design method of claim 3, wherein the predetermined angle range is 90° to 270°.

5. The design method of claim 1, wherein the distance rule comprises a spacing rule, which comprises that a gap width of a vertex on an edge to be greater than a minimum spacing value, and the design method comprises:
adding a concave patch in the angle rule violating region.

6. The design method of claim 5, wherein adding the concave patch comprising:
calculating a plurality of gap values of a plurality of vertices on a curved edge extending from the angle rule violating region;
determining a vertex on one of two edges forming the angle rule violating region as a selected vertex, the selected vertex having the gap value greater than or equal to the minimum spacing value;
determining an edge originating from the selected vertex across a gap with the minimum spacing value; and
using the edge to define the concave patch.

7. The design method of claim 6, wherein two intersection angles at both ends of the edge of the concave patch are both within a predetermined angle range.

8. The design method of claim 1, wherein the distance rule comprises a width rule which comprises that a patterned element width to be greater than or equal to a minimum width value, and the design method comprises:
removing a tip portion from the angle rule violating region.

9. The design method of claim 8, wherein removing the tip portion comprises:
calculating a plurality of width values of a plurality of vertices on a curved edge to a neighboring edge that together form the tip portion with the curved edge;
determining a vertex on one of two edges forming the angle rule violating region as a selected vertex, the selected vertex having the width value greater than or equal to the minimum width value;
determining an edge originating from the selected vertex across a patterned element with the minimum width value; and
using the edge to define the tip portion.

10. The design method of claim 9, wherein two intersection angles at both ends of the edge of the tip portion are both within a predetermined angle range.

11. An electronic device configured to check layout of a semiconductor device, the electronic device comprising:
a memory configured to store an instruction code; and
a processing circuit coupled to the memory to access the instruction code, the processing circuit being configured to perform the following steps according to the instruction code:
obtain a layout file;
check the layout file according to an angle rule to identify an angle rule violating region in the layout file;
check the layout file according to a distance rule to identify a distance rule violating region corresponding to the angle rule violating region in the layout file; and
modify the layout file according to the distance rule violating region to fix both of the angle rule violating region and the distance rule violating region.

12. The electronic device of claim 11, wherein the layout file is a graphical data system (GDS) file recording a plurality of vertices.

13. The electronic device of claim 11, wherein the angle rule comprises that an angle formed by three connected vertices is within a predetermined angle range.

14. The electronic device of claim 13, wherein the predetermined angle range is between 90° to 270°.

15. The electronic device of claim 11, wherein the distance rule comprises a spacing rule, which comprises that a gap width of a vertex on an edge to be greater than a minimum spacing value, and the processing circuit is configured to:
add a concave patch in the angle rule violating region.

16. The electronic device of claim 15, wherein the processing circuit is configured to:
calculate a plurality of gap values of a plurality of vertices on a curved edge extending from the angle rule violating region;
determine a vertex on one of two edges forming the angle rule violating region as a selected vertex, the selected vertex having the gap value greater than or equal to the minimum spacing value;
determine an edge originating from the selected vertex across a gap with the minimum spacing value; and
use the edge to define the concave patch.

17. The electronic device of claim 11, wherein the distance rule comprises a width rule which comprises that a patterned element width to be greater than or equal to a minimum width value, and the processing circuit is configured to:
remove a tip portion from the angle rule violating region.

18. The electronic device of claim 17, wherein the processing circuit is configured to:
calculate a plurality of width values of a plurality of vertices on a curved edge to a neighboring edge that together form the tip portion with the curved edge;
determine a vertex on one of two edges forming the angle rule violating region as a selected vertex, the selected vertex having the width value greater than or equal to the minimum width value;
determine an edge originating from the selected vertex across a patterned element with the minimum width value; and
use the edge to define the tip portion.

19. A non-transitory computer readable medium configured to instructions for execution by a processing circuit for:
obtaining a layout file;
checking the layout file according to an angle rule to identify an angle rule violating region in the layout file;
checking the layout file according to a distance rule to identify a distance rule violating region corresponding to the angle rule violating region in the layout file; and
modifying the layout file according to the distance rule violating region to fix both of the angle rule violating region and the distance rule violating region.

20. The non-transitory computer readable medium of claim 19, wherein the layout file is applied on an interposer.
